(19) United States
(12) Patent Application Publication
(10) Pub. No.: US 2023/0145923 A1
(43) Pub. Date: May 11, 2023

(54) VEHICLE AND CONTROL METHOD THEREOF

(71) Applicants: Hyundai Motor Company, Seoul (KR); Kia Corporation, Seoul (KR)

(72) Inventor: Sang Jae HAN, Hwaseong-Si (KR)

(73) Assignees: Hyundai Motor Company, Seoul (KR); Kia Corporation, Seoul (KR)

(21) Appl. No.: 17/900,523

(22) Filed: Aug. 31, 2022

(30) Foreign Application Priority Data
Nov. 5, 2021 (KR) 10-2021-0151114

(51) Int. Cl. B60L 58/12; B60R 16/033; B60L 3/00; B60W 20/00; H02J 7/00

(52) U.S. Cl. CPC B60L 58/12; B60L 3/0046; B60R 16/033; B60W 20/00; H02J 7/0013; H02J 7/0048; H02J 7/00712; B60W 2510/244; B60W 2710/305; H02J 2207/20

(57) ABSTRACT

A vehicle includes a main battery; an auxiliary battery; a plurality of loads connected to the main battery and auxiliary battery; a main controller configured to determine a total amount of available power according to an amount of available power of each of the main battery and the auxiliary battery; and a plurality of load controllers communicatively connected to the main controller and configured to receive the total amount of available power from the main controller and determine whether to operate each of the loads electrically connected to the load controllers based on the received total amount of available power, wherein the plurality of load controllers are configured to control to operate a load requiring an operation among the plurality of loads, when the total amount of available power determined by the main controller is greater than or equal to an amount of power required for the operation of the load requiring the operation.

### CROSS-REFERENCE TO RELATED APPLICATION

The present application claims priority to Korean Patent Application No. 10-2021-0151114, filed on Nov. 5, 2021 the entire contents of which is incorporated herein for all purposes by this reference.

### BACKGROUND OF THE PRESENT DISCLOSURE

### Field of the Present Disclosure

The present disclosure relates to a vehicle and a control method thereof, and more particularly, to a vehicle and a control method thereof that manages vehicle battery consumption.

### Description of Related Art

Recently, various convenience devices mounted on a vehicle are operated by receiving power from a vehicle battery.

As the update of the convenience functions, connectivity functions and various controllers of a vehicle are required while the vehicle is parked, the power consumption in the state where no electricity is being generated is increasing.

While parked, not driving, because electric power is generally supplied to a vehicle through an already charged battery, it is essential to secure the amount of available power in response to such an increase in electric power consumption while parked.

However, a state of the amount of charge of a battery is different depending on the existing driving state of the vehicle, the driving distance after charging, and the like, and also it is difficult to predict the state of the amount of charge of the battery. Furthermore, lead-acid-type and lithium-type batteries are mainly used for battery at 12 V level used by general electric controllers, but there is a limit to power supply with only a single battery in various conditions while parked.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing a vehicle and a control method thereof which may control battery power consumption while parked based on the amount of available power in a dual battery system to improve a power supply performance while parked.

According to an aspect of the present disclosure, there is provided a vehicle, including: a main battery; an auxiliary battery; a plurality of loads connected to the main battery and auxiliary battery; a main controller configured to determine a total amount of available power according to an amount of available power of each of the main battery and the auxiliary battery; and a plurality of load controllers communicatively connected to the main controller and configured to receive the total amount of available power from the main controller and determine whether to operate each of the loads electrically connected to the load controllers based on the received total amount of available power, wherein the plurality of load controllers are configured to control to operate a load requiring an operation among the plurality of loads, when the total amount of available power determined by the main controller is greater than or equal to an amount of power required for the operation of the load requiring the operation.

The plurality of load controllers are configured to determine whether to operate each of groups of the loads by grouping the plurality of loads according to operation characteristics of the loads.

The main controller is configured to determine an amount of discharge of each of the main battery and the auxiliary battery according to the amount of available power of each of the main battery and the auxiliary battery.

The main controller is configured to control the amount of discharge of each of the main battery and the auxiliary battery through a converter control of the auxiliary battery.

When a software update of the vehicle is required, the plurality of load controllers are configured to control to stop operations of the plurality of loads, except for a load required for the software update of the vehicle among the plurality of loads.

The main battery and the auxiliary battery have different types and characteristics each other.

The plurality of load controllers are configured to control to change an amount of power required for an operation of each of the loads according to an operation priority of the plurality of loads.

When the vehicle is an internal combustion engine vehicle, the amount of available power of the main battery is an amount of charged power greater than or equal to an amount of power required to start the vehicle, and when the vehicle is an electric vehicle or a hybrid vehicle, the amount of available power of the main battery is an amount of charged power greater than or equal to an amount of power required for cell protection of the vehicle.

The amount of available power of the auxiliary battery is an amount of charged power greater than or equal to an amount of power required for an operation of a load preset to be supplied with power by the auxiliary battery.

According to an aspect of the present disclosure, there is provided a method of controlling a vehicle, the control method including: determining an amount of available power of a main battery; determining an amount of available power of an auxiliary battery; determining a total amount of available power according to the amount of available power of each of the main battery and the auxiliary battery; and determining whether to operate each of loads connected to the main battery and the auxiliary battery based on the total amount of available power, wherein the determining of whether to operate each of the loads controls to operate a load requiring an operation among the plurality of loads, when the total amount of available power is greater than or equal to an amount of power required for the operation of the load requiring the operation.

The determining of whether to operate each of the loads determines whether to operate each of groups by grouping the plurality of loads according to operation characteristics of the loads.

The controlling to operate the load requiring the operation determines an amount of discharge of each of the main battery and the auxiliary battery according to the amount of available power of each of the main battery and the auxiliary battery.

The determining of the amount of discharge of each of the main battery and the auxiliary battery determines the amount of discharge of each of the main battery and the auxiliary battery through a converter control of the auxiliary battery.

When a software update of the vehicle is required, the determining of whether to operate each of the loads controls to stop operations of the plurality of loads, except for a load required for the software update of the vehicle among the plurality of loads.

The main battery and the auxiliary battery have different types and characteristics each other.

The determining of whether to operate each of the loads controls to change an amount of power required for an operation of each of the loads according to an operation priority of the plurality of loads.

When the vehicle is an internal combustion engine vehicle, the amount of available power of the main battery is an amount of charged power greater than or equal to an amount of power required to start the vehicle, and when the vehicle is an electric vehicle or a hybrid vehicle, the amount of available power of the main battery is an amount of charged power greater than or equal to an amount of power required for cell protection of the vehicle.

The amount of available power of the auxiliary battery is an amount of charged power greater than or equal to an amount of power required for an operation of a load preset to be supplied with power by the auxiliary battery.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 illustrates an exterior of a vehicle;

FIG. 2 illustrates an interior of a vehicle;

FIG. 3A and FIG. 3B illustrate a battery used for a vehicle;

FIG. 4 is a control block diagram of a battery management system of a vehicle;

FIG. 5A illustrates a main battery and an auxiliary battery of an internal combustion engine vehicle;

FIG. 5B illustrates a main battery and an auxiliary battery of an electric vehicle and a hybrid vehicle;

FIG. 6 is a diagram illustrating a plurality of loads classified into three groups;

FIG. 7 is a diagram illustrating a difference in the amount of discharge depending on the amount of available power of a battery;

FIG. 8 is a diagram illustrating that the amount of power required for operation of a load varies depending on an operation priority of the load; and

FIG. 9 and FIG. 10 are flowcharts illustrating a battery consumption management of a vehicle.

It may be understood that the appended drawings are not necessarily to scale, presenting a somewhat simplified representation of various features illustrative of the basic principles of the present disclosure. The specific design features of the present disclosure as disclosed herein, including, for example, specific dimensions, orientations, locations, and shapes will be determined in part by the particularly intended application and use environment.

In the figures, reference numbers refer to the same or equivalent parts of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Like reference numerals throughout the specification denote like elements. Also, the present specification does not describe all the elements according to various exemplary embodiments of the present disclosure, and descriptions well-known in the art to which the present disclosure pertains or overlapped portions are omitted. The terms such as “∼part”, “∼member”, “∼module”, “∼block”, and the like may refer to at least one process processed by at least one hardware or software. According to various exemplary embodiments of the present disclosure, a plurality of “∼part”, “∼member”, “∼module”, “∼block” may be embodied as a single element, or a single of “∼part”, “∼member”, “∼module”, “∼block” may include a plurality of elements.

It will be understood that when an element is referred to as being “connected” to another element, it may be directly or indirectly connected to the other element, wherein the indirect connection includes “connection” via a wireless communication network.

It will be understood that the term “include” when used in the exemplary embodiment, specifies the presence of stated features, integers, steps, operations, elements, and/or components, but do not preclude the presence or addition of one or more other features, integers, steps, operations, elements, components, and/or groups thereof.

It will be understood that when it is stated in the exemplary embodiment that a member is located “on” another member, not only a member may be in contact with another member, but also yet another member may be present between the two members.

It will be understood that, although the terms first, second, etc. may be used herein to describe various elements, these elements should not be limited by these terms.

It is to be understood that the singular forms are intended to include the plural forms as well, unless the context clearly dictates otherwise.

Reference numerals used for method steps are just used for convenience of explanation, but not to limit an order of the steps. Thus, unless the context clearly dictates otherwise, the written order may be practiced otherwise.

Hereinafter, an operation principle and embodiments will be described in detail with reference to the accompanying drawings.

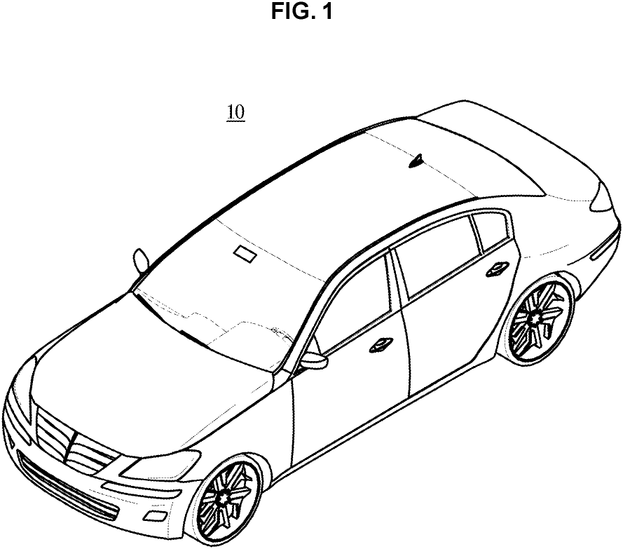

FIG. 1 illustrates an exterior of a vehicle.

Referring to FIG. 1, a vehicle 10 according to an exemplary embodiment of the present disclosure includes vehicle wheels for moving the vehicle 10, doors for shielding interior of the vehicle 10 from an outside, a windshield for providing a driver inside the vehicle 10 with a front field of view of the vehicle 10, and side mirrors for providing the driver with a rear field of view of the vehicle 10.

The doors are rotatably provided on the left and right sides of the vehicle 10 so that the driver or an occupant get in the vehicle 10 when opened, and the interior of the vehicle 10 is shielded from the outside, when closed. A door handle for opening and closing the door may be provided on an external surface of the vehicle 10, and an antenna for transmitting a communication signal may be mounted on the door handle. Although the door handles on the driver’s seat side are illustrated, an antenna configured for transmitting a communication signal may be mounted on a door handle on a passenger seat side as well. That is, at least one of the left handle or right handle may be provided with an antenna. Also, antennae configured for transmitting/receiving a communication signal may be mounted on various places inside the vehicle 10.

The windshield is provided on a front upper side of the vehicle 10 so that the driver inside the vehicle 1 may obtain visual information related to the front of the vehicle 1. The windshield is also referred to as a windshield glass.

Also, the side mirrors include the left side mirror positioned on the left side of the vehicle 10 and the right side mirror positioned on the right side of the vehicle 10. The side mirrors may provide the driver inside the vehicle 10 with visual information related to a field of view behind and to the sides of the vehicle 10.

Furthermore, the vehicle 10 may include detection devices such as a proximity sensor configured for detecting an obstacle or another vehicle located on the rear or sides of the vehicle 10, a rain sensor configured for detecting rain and precipitation, a radar sensor, etc., without being limited thereto. The vehicle 10 may further include a camera, a weight sensor, and the like, for identifying an occupant inside the vehicle 10.

Meanwhile, the proximity sensor may transmit a detection signal to the sides or the rear of the vehicle 10 and receive a reflection signal reflected from an obstacle such as another vehicle, etc. The proximity sensor may detect whether an obstacle on the sides or rear of the vehicle 10 exists based on a waveform of the received reflection signal, and detect a position of the obstacle. As an example of the proximity sensor described above, a method of transmitting ultrasonic waves or infrared rays and detecting a distance to an obstacle using the ultrasonic waves or infrared rays reflected from the obstacle may be used. For instance, the proximity sensor may include at least one of a radar sensor or a light detection and ranging (LiDAR) sensor, without being limited thereto.

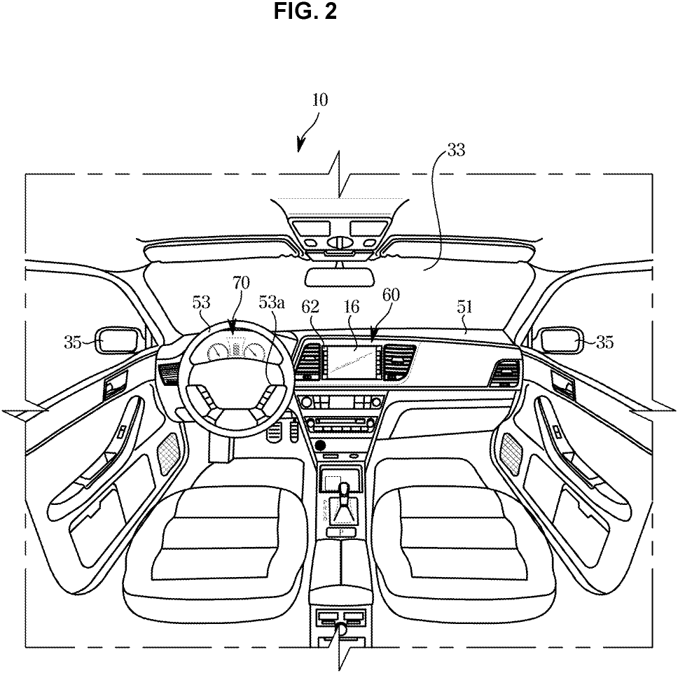

FIG. 2 illustrates an interior of a vehicle.

Referring to FIG. 2, inside the vehicle 10, a dashboard 51 provided with various devices for a driver to control the vehicle 10, a driver’s seat on which the driver sits, cluster portions 70 for displaying operation information of the vehicle 10, and a navigation 60 for providing route information according to a driver’s operation command are included. In the present instance, the navigation 60 may be an audio video navigation (AVN) device configured for providing an audio function and video function as well as the route information.

The dashboard 51 is provided to be protruded from a lower portion of a windscreen toward the driver, and allows the driver to operate various devices provided on the dashboard 51.

The driver’s seat is provided at the rear of the dashboard 51, so that the driver may stably operate the vehicle 10 while watching the front of the vehicle 10 and various devices on the dashboard 51.

The cluster portions 70 are provided on the driver’s seat side of the dashboard 51, and may include the speed gauge for displaying a travelling speed and the revolutions per minute (RPM) gauge for displaying a rotation speed of a power device.

The navigation 60 may include a display 16 for displaying a route to a destination or information related to roads on which the vehicle 10 is travelling and a speaker for outputting a sound according to the driver’s operation command.

In addition to the above-described configuration, the vehicle 10 may include the power device configured for rotating vehicle wheels, a steering device configured for changing a moving direction of the vehicle 10, and a braking device configured for stopping movement of the vehicle wheels.

The power device may provide a rotation force to front wheels or rear wheels so that a vehicle body of the vehicle 10 moves forward or backward thereof. The power device may include an engine that generates the rotation force by burning fossil fuel or a motor that generates the rotation force by receiving power from a capacitor.

The steering device may include a steering wheel 53 that receives a driving direction input from the driver, a steering gear that converts a rotation motion of the steering wheel 53 into reciprocating motion, and a steering link that transmits the reciprocating motion of the steering gear to the front wheels. The steering device may change the driving direction of the vehicle 10 by changing a direction of a rotation shaft of the wheel.

The braking device may include a brake pedal that receives a braking operation from the driver, a brake drum connected to the wheels, a brake shoe that brakes a rotation of the brake drum using friction force, and the like. The braking device may brake the vehicle 10 by stopping the rotation of the wheels.

Loads 15 to perform various functions exist inside the vehicle 10, and a certain amount of power is required for the loads 15 to operate. Recently, a variety of functions for driver convenience have been developed, and thus the use of convenient functions while parked are also increasing.

Hereinafter, management of the amount of available power of a battery of the vehicle 10 in response to an increase in the use of convenient functions is described in detail.

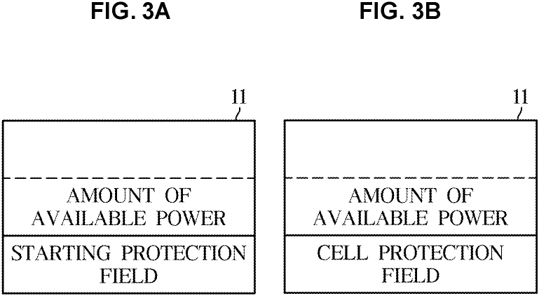

FIG. 3A and FIG. 3B illustrate a battery used for a vehicle.

A battery is a device configured for supplying power to the plurality of loads 15 provided in the vehicle 10. The battery may include a high voltage battery or a low voltage battery.

The high voltage battery may be applied to driving of the vehicle 10, and the low voltage battery may be applied to accessories of the vehicle 10 such as a radio, air conditioner, navigation, and the like, without being limited thereto.

As described above, the battery of the vehicle 10 may supply power to operate a plurality of devices in the vehicle to allow a user of the vehicle 10 to use various functions.

The vehicle 10 may include an internal combustion engine vehicle 10 and an eco-friendly vehicle 10 according to a power source. Here, the internal combustion engine vehicle 10 controls a start of the vehicle 10 by use of a battery, and when the start is complete, generates mechanical power by burning petroleum fuel such as gasoline or diesel to drive using the mechanical power. The eco-friendly vehicle 10 is driven by use of electricity from the battery as the power source to reduce fuel efficiency and emission of harmful gases.

Also, the eco-friendly vehicle 10 may include an electric vehicle 10 and a hybrid vehicle 10. The electric vehicle 10 includes a motor and a battery which is a rechargeable power source, and rotates the motor with electricity accumulated in the battery to drive vehicle wheels using the rotation of the motor. The hybrid vehicle 10 includes an engine, a battery and a motor, and controls electric power of the motor and mechanical power of the engine to drive the vehicle.

The internal combustion engine vehicle 10 mainly utilizes a lead-acid battery, and the electric vehicle 10 and the eco-friendly vehicle 10 mainly use a lithium battery, as a battery of the vehicle 10.

Power of the lead-acid battery of the internal combustion engine vehicle 10 may be divided into a starting protection field required for starting the vehicle 10, and the amount of available power for supplying power to the plurality of loads 15 in the vehicle 10 as shown in FIG. 3A.

The starting protection field refers to power required to always be secured because a certain amount of power is required when starting the vehicle 10 with the ignition turned off. For the lead-acid battery, approximately 60 % of the total amount of charge is required to be secured.

The amount of available power refers to the amount of power obtained by subtracting the amount of power required for starting the vehicle 10 from the total amount of charged power of the lead-acid battery, and the plurality of loads 15 of the vehicle 10 may be supplied with power using the available power.

Power of the lithium battery of the electric vehicle 10 and the hybrid vehicle 10 may be divided into a cell protection field required for cell protection of the battery and the amount of available power for supplying power to the plurality of loads 15 in the vehicle 10 as shown in FIG. 3B.

The amount of available power refers to the amount of power obtained by subtracting the amount of power required for cell protection from the total amount of charged power of the lithium battery, and the plurality of loads 15 in the vehicle 10 may be supplied with power using the available power.

The plurality of loads 15 in the vehicle 10 may be supplied with power using the battery of the vehicle 10 as described above, allowing the user to use various functions of the vehicle 10.

Recently, various functions of the vehicle 10 are being frequently used when the battery of the vehicle 10 may not be charged, such as parking, and thus an efficient management of the amount of available power of the battery of the vehicle 10 is highly required.

Accordingly, hereinafter, an efficient management of the amount of available power of the vehicle 10 by further mounting an auxiliary battery 12 in addition to a main battery 11 of the vehicle 10 is described in detail.

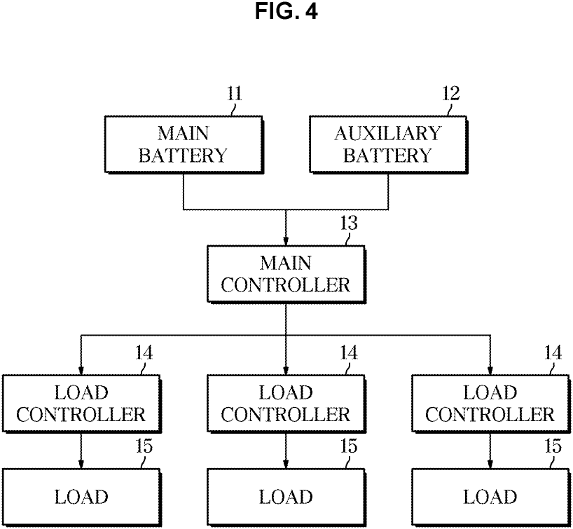

FIG. 4 is a control block diagram of a battery management system of a vehicle.

The vehicle 10 may include the main battery 11, the auxiliary battery 12, a main controller 13, a plurality of load controllers 14 and the plurality of loads 15.

As described above, the main battery 11 refers to a main battery of the vehicle 10 configured for storing power required for starting the vehicle 10 or cell protection and supplying power to each of the loads 15.

The auxiliary battery 12 is additionally mounted in addition to the main battery 11, and may additionally supply power to the plurality of loads 15 of the vehicle 10.

The main controller 13 may determine the amount of available power of the main battery 11 and the amount of available power of the auxiliary battery 12.

Also, the main controller 13 may determine the total amount of available power by adding the amount of available power of the main battery 11 and the amount of available power of the auxiliary battery 12.

According to the exemplary embodiment of the present disclosure, a unit of the amount of available power is [Ah] which is the amount of electric charge transferred at 1 ampere for one hour, not [%] which is a ratio of a current amount of charge to a total amount of charge as a unit of an existing state of charge (SoC). The actual amount of available power even between batteries having different amounts of charge, rather than a ratio of available power, is determined, and thus the sum of the amount of available power of different batteries may be easily determined.

Accordingly, the main controller 13 may determine the total amount of available power by easily adding the amount of available power of the main battery 11 and the amount of available power of the auxiliary battery 12, through the determination of the amount of power of the battery using the [Ah] unit.

The load controllers 14 may receive information related to the total amount of available power determined by the main controller 13 from the main controller 13.

The load controllers 14 may determine whether to operate each of the loads 15 based on the received total amount of available power.

The loads 15 may be devices that allow the vehicle 10 to be driven/braked/steered or provide a driver of the vehicle 10 with convenience, by consuming power supplied from the battery.

For example, the loads 15 may include an engine management system (EMS), a transmission control unit (TCU), an electronic brake control module (EBCM), a motor-driven power steering (MDPS), a body control module (BCM), an audio device, a heating/ventilation/air conditioning (HVAC) device, a navigation device, a power seat, a seat heater, a headlight, and the like.

The loads 15 require a certain amount of power to operate.

The load controllers 14 may determine whether to operate each of the loads 15 by comparing the amount of power required for an operation of each of the loads 15 to the total amount of available power received from the main controller 13.

With respect to a load required to be operated by a user or by the needs of the vehicle 10, by comparing the amount of power required for an operation of the load requiring the operation with the total amount of available power received from the main controller 13, when the total amount of available power is greater than or equal to the amount of power required for the operation of the load, the load controller 14 may control to operate the corresponding load 15.

The main controller 13, the plurality of load controllers 14 and the plurality of loads 15 may communicate with each other through a communication network in the vehicle 10. For example, the main controller 13, the plurality of load controllers 14 and the plurality of loads 15 may exchange data through an Ethernet, a media oriented systems transport (MOST), a Felxray, a controller area network (CAN), a local interconnect network (LIN), and the like.

Accordingly, the determination on the total amount of available power of the battery of the vehicle 10 and the determination on whether to operate each of the loads 15 are independently made in the main controller 13 and the plurality of load controllers 14, respectively. Accordingly, the communication amount of the vehicle 10 may be reduced and an operation process may be simplified.

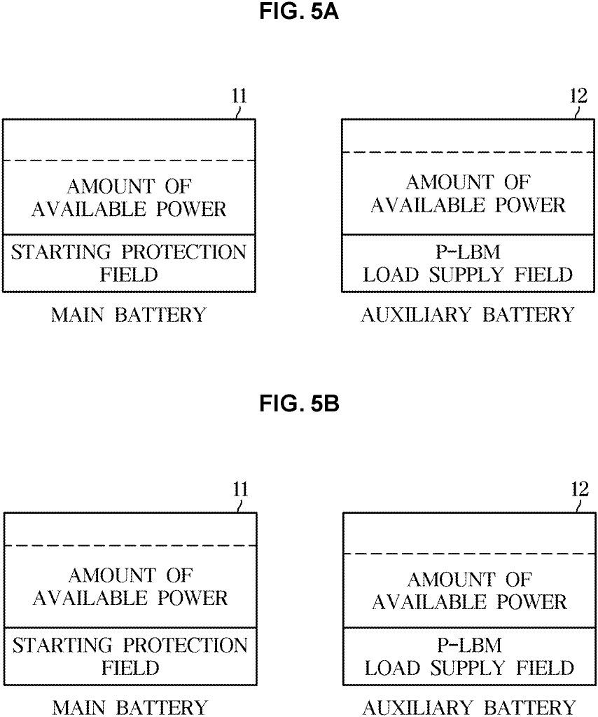

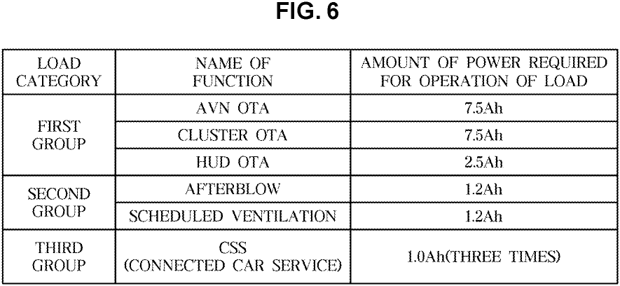

FIG. 5 illustrates the main battery 11 and the auxiliary battery 12.

As described above, the vehicle 10 may be divided into the internal combustion engine vehicle 10 and the electric and hybrid vehicle 10. The internal combustion engine vehicle 10 mainly utilizes a lead-acid battery, and the electric and hybrid vehicle 10 mainly use a lithium battery.

FIG. 5A illustrates a main battery and an auxiliary battery of the internal combustion engine vehicle.

In the main battery 11, the amount of available power is defined as the amount of charge greater than or equal to the amount of power required for starting the vehicle 10. In the auxiliary battery 12, the amount of available power is defined as a P-LBM load 15 supply field, i.e., the amount of charge greater than or equal to the amount of power required for an operation of the load 15 which is preset to be supplied with power by the auxiliary battery 12.

For example, the operation of the load 15 which is preset to be supplied with power by the auxiliary battery 12 may include an operation of a black box, etc.

FIG. 5B illustrates a main battery and an auxiliary battery of an electric and hybrid vehicle.

In the main battery 11, the amount of available power is defined as the amount of charge greater than or equal to the amount of power required for cell protection of the battery of the vehicle 10. In the auxiliary battery 12, the amount of available power is defined as a P-LBM load 15 supply field, i.e., the amount of charge greater than or equal to the amount of power required for an operation of the load 15 which is preset to be supplied with power by the auxiliary battery 12.

Accordingly, all of the internal combustion engine vehicle 10, the electric vehicle 10 and hybrid vehicle 10 may further include the auxiliary battery 12 in addition to the main battery 11, and each of the batteries may have different types and characteristics each other.

The internal combustion engine vehicle 10 may use a lead-acid battery as the main battery 11, and a lithium battery as the auxiliary battery 12.

The lead-acid battery may use approximately 60% to 90% of its total battery capacity as power which may be supplied to the loads 15 of the vehicle 10, and the lithium battery may use approximately 10% to 95% of its total battery capacity as power which may be supplied to the loads 15 of the vehicle 10.

Also, the capacity of the main battery 10 is 100 Ah, and that of the auxiliary battery 12 is 30 Ah, i.e., the capacities of the main battery 10 and the auxiliary battery 12 may be different.

Furthermore, as the types of the main battery 10 and the auxiliary battery 12 are different, their charging/discharging characteristics may be different.

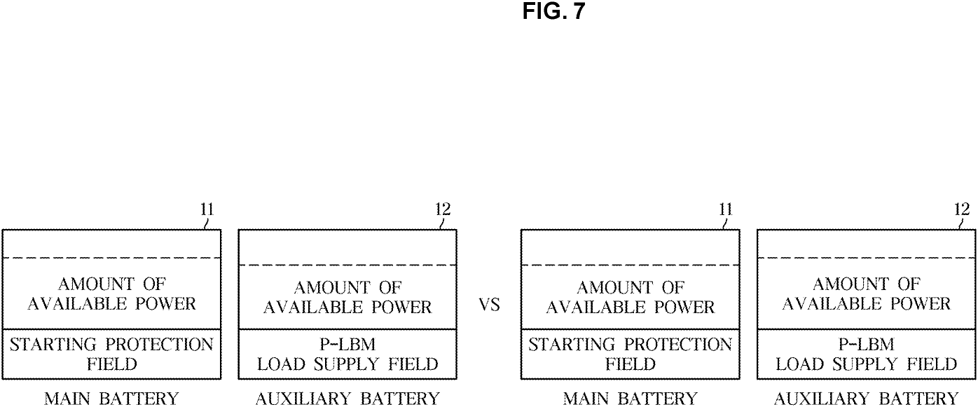

FIG. 6 is a diagram illustrating the plurality of loads 15 classified into three groups.

Each of the loads 15 provided in the vehicle 10 performs different operations. When the loads 15 performing similar operations are grouped and managed, the management of the grouped loads 15 may be facilitated.

For example, the load 15 that performs a scheduled ventilation operation for ventilation inside the vehicle 10 and the load 15 that performs an afterblow operation for preventing odor and mold growth in an air conditioner of the vehicle 10 by drying an air vent using an air conditioner motor may be grouped due to their similar operation characteristics.

Also, all of an AVN over-the-air (OTA) programming for updating an AVN provided in the vehicle 10, a CLUSTER OTA for updating a cluster of the vehicle 10, and a head up display (HUD) OTA for updating a head up display of the vehicle 10 perform software updates. Accordingly, the AVN OTA, the CLUSTER OTA and the HUD OTA may be grouped due to their similar operation characteristics.

Referring to FIG. 6, the loads 15 related to the software update are classified as a first group, the loads 15 related to operations of the air conditioner in the vehicle 10 are classified as a second group, and the loads 15 related to a connected car service (CSS) is classified as a third group.

Accordingly, by grouping the loads 15 including similar operation characteristics and independently managing the operations of a single group of loads 15 by a single load controller 14, battery consumption management related to the operations of the loads 15 may be facilitated.

As described above, the main controller 13 determines the total amount of available power, the plurality of load controllers 14 determine whether to operate the plurality of loads 15 or a group of the plurality of loads 15, and in the present instance, a software update of the vehicle 10 may be urgently required.

For instance, updates to the main controller 13 and the load controllers 14 are urgently required, and such software update may consume a large amount of power.

Accordingly, in the instant case, with respect to the plurality of loads 15 except for the load 15 required for the software update, the load controllers 14 may control the corresponding load 15 not to operate or the corresponding load 15 which is already operating to stop the operation, even when the total amount of available power is greater than the amount of power required for the operation of the corresponding load 15.

Thus, a delay of the software update required to be urgently made in the vehicle 10 may be minimized.

In an exemplary embodiment of the present invention, the main controller 13 and the load controllers 14 may be integrated into a single controller.

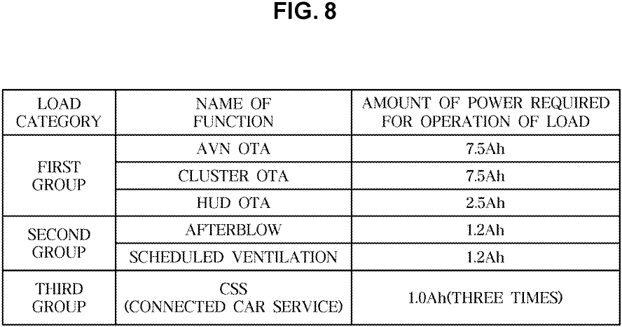

FIG. 7 is a diagram illustrating a difference in the amount of discharge depending on the amount of available power of a battery.

The amount of available power of each of the main battery 11 and the auxiliary battery 12 may vary depending on a driving state of the vehicle 10 and a charging/discharging state of each of the batteries.

In the present instance, when power of only one of the batteries is used, the battery in use may be completely discharged, and thus power required may not be supplied and a durability of the battery may deteriorate.

To prevent the above, the main controller 13 may determine the amount of available power of each of the main battery 11 and the auxiliary battery 12, and determine the amount of discharge based on the amount of available power of each of the main battery 11 and the auxiliary battery 12.

For example, when the amount of available power of the main battery 11 is greater than the amount of available power of the auxiliary battery 12, the main controller 13 may control to consume the available power of the main battery 11 first.

By contrast, when the amount of available power of the auxiliary battery 12 is greater than the amount of available power of the main battery 11, the main controller 13 may control to consume the available power of the auxiliary battery 12 first.

When controlling the amount of discharge based on the amount of available power of each of the main battery 11 and the auxiliary battery 12, the main controller 13 may control the amount of discharge of the main battery 11 and the auxiliary battery 12 using a converter control.

The main controller 13 may allow a voltage corresponding to a desired discharge current to be applied by use of the converter control.

By determining the amount of discharge according to a ratio of the amount of available power of the main battery 11 and the auxiliary battery 12 as described above, complete discharge of one of the batteries and deterioration of durability of the batteries may be prevented.

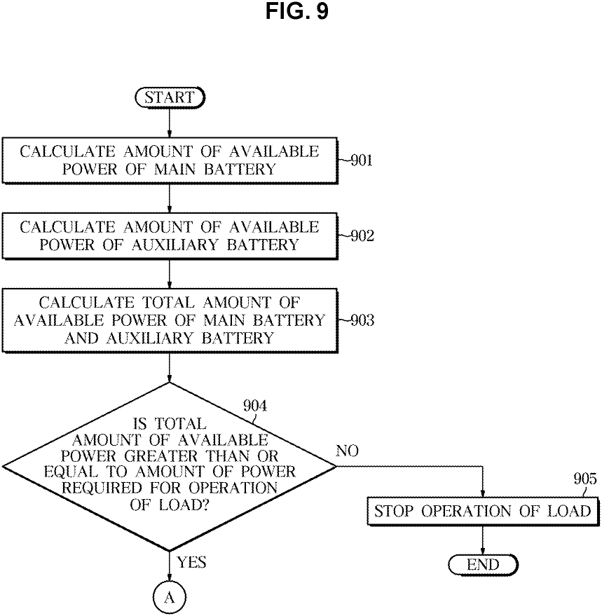

FIG. 8 is a diagram illustrating that the amount of power required for an operation of the load 15 varies in accordance with an operation priority of the load 15.

It may be confirmed in FIG. 8 that, when an OTA operation is not urgent, the amount of required power of a first group, i.e., the loads 15 related to OTA, increases.

Also, it may be confirmed that, when the OTA operation is urgent, the amount of required power of a second group, i.e., the loads 15 related to an operation of air conditioner, increases.

In summer, because the number of operations of air conditioner in the vehicle 10 is increased, an afterblow operation is required more frequently after an end of driving. In the present instance, an operation of the loads 15 corresponding to the second group is required. When the afterblow operation is prioritized over the operation of the first group, i.e., the loads 15 related to OTA, a priority of the afterblow operation may be increased by increasing the amount of power required for the OTA operation for the afterblow operation to be performed first.

When the existing amount of power required for an operation of the loads 15 corresponding to the first group is 7.5 Ah, the amount of required power may be changed to 8.7 Ah (7.5 Ah + 1.2 Ah) to increase the priority of the afterblow operation.

By contrast, when the software update of the vehicle 10 is prioritized over the afterblow operation, a priority of the OTA operation may be increased by increasing the amount of power required for the afterblow operation for the OTA operation to be performed first.

When the existing amount of power required for an operation of the loads 15 corresponding to the second group is 1.2 Ah, the amount of required power may be changed to 8.7 Ah (1.2 Ah + 7.5 Ah) to increase the priority of the OTA operation.

As described above, an operation required for the vehicle 10 more may be controlled to be performed first, by varying the amount of required power depending on the operation priority of the load 15.

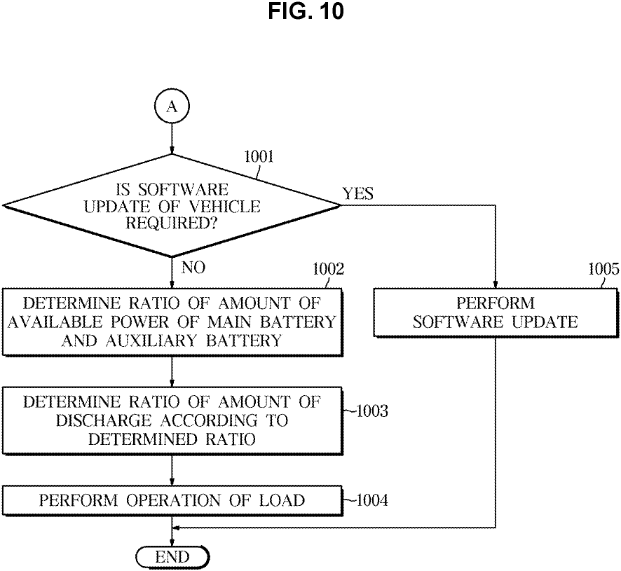

FIG. 9 and FIG. 10 are flowcharts illustrating a battery consumption management of a vehicle.

First of all, the amount of power which may be supplied by a battery to operate the loads 15 is required to be determined.

First, the amount of available power of the main battery 11 may be determined (901). Next, the amount of available power of the auxiliary battery 12 may be determined (902).

Afterwards, the total amount of available power may be determined by adding the amount of available power of the main battery 11 and the amount of available power of the auxiliary battery 12 (903).

When the total amount of available power is less than the amount of power required for an operation of the load 15 (No in operation 904), the load 15 may be controlled not to be operated or, when the load 15 is being operated, the operation of the load 15 may be controlled to be stopped (905).

When the total amount of available power is greater than or equal to the amount of power required for the operation of the load 15 (Yes in operation 904), whether a software update of the vehicle 10 is urgently required may be determined (1001).

When the software update of the vehicle 10 is required (Yes in operation 1001), the operation of the load 15 may be stopped and the software update of the vehicle 10 may be performed (1005).

When the software update of the vehicle 10 is not required (No in operation 1001), a ratio of the amount of available power of the main battery 11 and the auxiliary battery 12 may be determined (1002).

A ratio of the amount of discharge of the main battery 11 and the auxiliary battery 12 may be determined according to the determined ratio of the amount of available power of the main battery 11 and the auxiliary battery 12 (1003).

When the amount of available power of the main battery 11 is greater than the amount of available power of the auxiliary battery 12, the amount of available power of the main battery 11 may be controlled to be consumed first.

By contrast, when the amount of available power of the auxiliary battery 12 is greater than the amount of available power of the main battery 11, the main controller 13 may control to consume the available power of the auxiliary battery 12 first.

When the ratio of the amount of discharge of the main battery 11 and the auxiliary battery 12 is determined, the available power of the main battery 11 or the auxiliary battery 12 may be supplied to the load 15 that requires an operation, according to the determined ratio, and thus the operation of the load 15 may be performed (1004).

Accordingly, the amount of available power of the battery of the vehicle 10 may be easily determined, and battery power consumption of the vehicle 10 may be easily managed by determining whether to operate the load 15, through comparison of the amount of available power and the amount of power required for operation of the load 15.

As is apparent from the above, according to the exemplary embodiments of the present disclosure, the vehicle and the control method thereof can simplify the control of battery power consumption while parked and improve the management of the amount of available power.

Furthermore, the term related to a control device such as “controller”, “control apparatus”, “control unit”, “control device”, “control module”, or “server”, etc refers to a hardware device including a memory and a processor configured to execute one or more steps interpreted as an algorithm structure. The memory stores algorithm steps, and the processor executes the algorithm steps to perform one or more processes of a method in accordance with various exemplary embodiments of the present disclosure. The control device according to exemplary embodiments of the present disclosure may be implemented through a nonvolatile memory configured to store algorithms for controlling operation of various components of a vehicle or data about software commands for executing the algorithms, and a processor configured to perform operation to be described above using the data stored in the memory. The memory and the processor may be individual chips. Alternatively, the memory and the processor may be integrated in a single chip. The processor may be implemented as one or more processors. The processor may include various logic circuits and operation circuits, may process data according to a program provided from the memory, and may generate a control signal according to the processing result.

The control device may be at least one microprocessor operated by a predetermined program which may include a series of commands for carrying out the method included in the aforementioned various exemplary embodiments of the present disclosure.

The aforementioned invention can also be embodied as computer readable codes on a computer readable recording medium. The computer readable recording medium is any data storage device that can store data which may be thereafter read by a computer system and store and execute program instructions which may be thereafter read by a computer system. Examples of the computer readable recording medium include Hard Disk Drive (HDD), solid state disk (SSD), silicon disk drive (SDD), read-only memory (ROM), random-access memory (RAM), CD-ROMs, magnetic tapes, floppy discs, optical data storage devices, etc and implementation as carrier waves (e.g., transmission over the Internet). Examples of the program instruction include machine language code such as those generated by a compiler, as well as high-level language code which may be executed by a computer using an interpreter or the like.

In various exemplary embodiments of the present disclosure, each operation described above may be performed by a control device, and the control device may be configured by a plurality of control devices, or an integrated single control device.

In various exemplary embodiments of the present disclosure, the control device may be implemented in a form of hardware or software, or may be implemented in a combination of hardware and software.

Furthermore, the terms such as “unit”, “module”, etc. included in the specification mean units for processing at least one function or operation, which may be implemented by hardware, software, or a combination thereof.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The foregoing descriptions of predetermined exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A vehicle, comprising:
a main battery;
an auxiliary battery;
a plurality of loads connected to the main battery and auxiliary battery;
a main controller configured to determine a total amount of available power according to an amount of available power of each of the main battery and the auxiliary battery; and
a plurality of load controllers communicatively connected to the main controller and configured to receive the total amount of available power from the main controller and determine whether to operate each of the loads electrically connected to the load controllers based on the received total amount of available power,
wherein the plurality of load controllers are configured to control to operate a load requiring an operation among the plurality of loads, when the total amount of available power determined by the main controller is greater than or equal to an amount of power required for the operation of the load requiring the operation.

2. The vehicle of claim 1, wherein the plurality of load controllers are configured to determine whether to operate each of groups of the loads by grouping the plurality of loads according to operation characteristics of the loads.

3. The vehicle of claim 1, wherein the main controller is configured to determine an amount of discharge of each of the main battery and the auxiliary battery according to the amount of available power of each of the main battery and the auxiliary battery.

4. The vehicle of claim 3, wherein the main controller is configured to determine a ratio of the amount of discharge of the main battery to the amount of discharge of the auxiliary battery and to supply the available power of the main battery and the auxiliary battery to the load that requires the operation, according to the determined ratio.

5. The vehicle of claim 3, wherein the main controller is configured to control the amount of discharge of each of the main battery and the auxiliary battery through a converter control of the auxiliary battery.

6. The vehicle of claim 1, wherein, when a software update of the vehicle is required, the plurality of load controllers are configured to control to stop operations of the plurality of loads, except for a load required for the software update of the vehicle among the plurality of loads.

7. The vehicle of claim 1, wherein the main battery and the auxiliary battery have different types and characteristics each other.

8. The vehicle of claim 1, wherein the plurality of load controllers are configured to control to change an amount of power required for an operation of each of the loads according to an operation priority of the plurality of loads.

9. The vehicle of claim 1, wherein, when the vehicle is an internal combustion engine vehicle, the amount of available power of the main battery is an amount of charged power greater than or equal to an amount of power required to start the vehicle, and
when the vehicle is an electric vehicle or a hybrid vehicle, the amount of available power of the main battery is an amount of charged power greater than or equal to an amount of power required for cell protection of the vehicle.

10. The vehicle of claim 1, wherein the amount of available power of the auxiliary battery is an amount of charged power greater than or equal to an amount of power required for an operation of a load preset to be supplied with power by the auxiliary battery.

11. A method of controlling a vehicle, the method comprising:
determining, by a controller, an amount of available power of a main battery;
determining, by the controller, an amount of available power of an auxiliary
determining, by the controller, a total amount of available power according to the amount of available power of each of the main battery and the auxiliary battery; and
determining, by the controller, whether to operate each of loads connected to the main battery and the auxiliary battery based on the total amount of available power,
wherein in the determining of whether to operate each of the loads, the controller is configured to control to operate a load requiring an operation among the plurality of loads, when the controller concludes that the total amount of available power is greater than or equal to an amount of power required for the operation of the load requiring the operation.

12. The method of claim 11, wherein in the determining of whether to operate each of the loads, the controller is configured to determine whether to operate each of groups by grouping the plurality of loads according to operation characteristics of the loads.

13. The method of claim 11, wherein in the controlling to operate the load requiring the operation, the controller is configured to determine an amount of discharge of each of the main battery and the auxiliary battery according to the amount of available power of each of the main battery and the auxiliary battery.

14. The method of claim 13, wherein the controller is configured to determine a ratio of the amount of discharge of the main battery to the amount of discharge of the auxiliary battery and to supply the available power of the main battery and the auxiliary battery to the load that requires the operation, according to the determined ratio.

15. The method of claim 13, wherein in the determining of the amount of discharge of each of the main battery and the auxiliary battery, the controller is configured to determine the amount of discharge of each of the main battery and the auxiliary battery through a converter control of the auxiliary battery.

16. The method of claim 11, wherein, when a software update of the vehicle is required, in the determining of whether to operate each of the loads, the controller is configured to control to stop operations of the plurality of loads, except for a load required for the software update of the vehicle among the plurality of loads.

17. The method of claim 11, wherein the main battery and the auxiliary battery have different types and characteristics each other.

18. The method of claim 11, wherein in the determining of whether to operate each of the loads, the controller is configured to control to change an amount of power required for an operation of each of the loads according to an operation priority of the plurality of loads.

19. The method of claim 11, wherein, when the vehicle is an internal combustion engine vehicle, the amount of available power of the main battery is an amount of charged power greater than or equal to an amount of power required to start the vehicle, and
when the vehicle is an electric vehicle or a hybrid vehicle, the amount of available power of the main battery is an amount of charged power greater than or equal to an amount of power required for cell protection of the vehicle.

20. The method of claim 11, wherein the amount of available power of the auxiliary battery is an amount of charged power greater than or equal to an amount of power required for an operation of a load preset to be supplied with power by the auxiliary battery.
